(19) United States
(12) Patent Application Publication
(10) Pub. No.: US 2025/0233007 A1
(43) Pub. Date: Jul. 17, 2025

(54) SUBSTRATE LIFT ASSEMBLY, SYSTEM INCLUDING THE ASSEMBLY, AND METHODS OF USING SAME

(71) Applicant: ASM IP Holding B.V., Almere (NL)

(72) Inventors: Tilakraj Durgadahalli Shankaregowda, Chandler, AZ (US); Sudhanshu Biyani, Tempe, AZ (US); Matthew Ricketts, Scottsdale, AZ (US); Ryan Joseph Paull, Gilbert, AZ (US); Paul Ma, Scottsdale, AZ (US); Shubham Garg, Gilbert, AZ (US); Arjav Vashi, Tempe, AZ (US); Todd Robert Dunn, Cave Creek, AZ (US); Rajmohan Muthaiah, Phoenix, AZ (US); Eric James Shero, Phoenix, AZ (US); Shuyang Zhang, Chandler, AZ (US); Samer Banna, Phoenix, AZ (US); Jereld Lee Winkler, Gilbert, AZ (US); Koji Tanaka, Tokyo (JP); Xu Huang, Mesa, AZ (US); Akanksha Harish, Phoenix, AZ (US)

(21) Appl. No.: 19/013,313

(22) Filed: Jan. 8, 2025

Related U.S. Application Data
(60) Provisional application No. 63/620,598, filed on Jan. 12, 2024.

(51) Int. Cl. H01L 21/687; C23C 16/458; C23C 16/52; H01L 21/67

(52) U.S. Cl. CPC H01L 21/68742; C23C 16/4581; C23C 16/4585; C23C 16/52; H01L 21/67259; H01L 21/67288; H01L 21/68757

(57) ABSTRACT

A substrate lift pin assembly, a system including the assembly, and methods of using the same are disclosed. The assembly can include one or more lift pins and a sensor to determine one or more of presence and condition information of the one or more lift pins. The system can be configured to provide an alarm and/or to cease operations based on the presence and/or condition information.

### CROSS-REFERENCE TO RELATED APPLICATIONS

This application is a nonprovisional of, and claims priority to and the benefit of, U.S. Provisional Patent Application No. 63/620,598, filed Jan. 12, 2024 and entitled “SUBSTRATE LIFT ASSEMBLY, SYSTEM INCLUDING THE ASSEMBLY, AND METHODS OF USING SAME,” which is hereby incorporated by reference herein.

### FIELD OF THE DISCLOSURE

The present disclosure relates generally to substrate processing systems, and more particularly, to methods and apparatus for detecting presence and/or condition of one or more lift pins in such systems.

### BACKGROUND OF THE DISCLOSURE

Substrate processing apparatus can be used for a variety of applications. For example, substrate processing apparatus can be used during the manufacture of electronic devices, such as semiconductor devices, photovoltaic devices, and the like.

Typical electronic device manufacturing includes gas-phase deposition, etching, and/or cleaning of substrates. During such processing, a substrate is typically placed on a susceptor within a reaction chamber of a reactor system.

In some reactor system designs, including a number of ALD reactor systems or apparatus, a substrate is loaded onto the susceptor when the susceptor is in a load/unload position and then the susceptor moves to a processing position for processing using a susceptor lift or elevator. When processing is completed, the susceptor can be moved to the load/unload position.

To facilitate loading and unloading of substrates to and from the susceptor, lift pins can be used to raise the substrate above the susceptor surface when the susceptor is in the load/unload position.

Due to several factors, the lift pins can become stuck, damaged, or even break, which can result in substrate damage or breakage or displacement of a substrate, which can affect substrate processing—e.g., lead to higher non-uniformity of an etch, clean, and/or deposition process. Often, stuck or damaged lift pins can go undetected for a period of time. Consequently multiple substrates may be affected before a problem is detected.

Existing design approaches to detect damages or broken lift pins may not be widely adopted or effective. Hence, there is a demand for apparatus and methods to accurately and cost effectively detect the occurrence of displaced or damaged lift pins and to alert the user of a reactor system and/or to automatically stop production until the issue can be identified and resolved.

Any discussion of problems and solutions involved in the related art has been included in this disclosure solely for the purposes of providing a context for the present disclosure and should not be taken as an admission that any or all of the discussion was known at the time the invention was made.

### SUMMARY OF THE DISCLOSURE

This summary is provided to introduce a selection of concepts in a simplified form. These concepts are described in further detail in the detailed description of example embodiments of the disclosure below. This summary is not intended to necessarily identify key features or essential features of the claimed subject matter, nor is it intended to be used to limit the scope of the claimed subject matter.

The present disclosure generally relates to substrate lift assemblies that use lift pins to facilitate loading and unloading of substrates, such as wafers to and from a susceptor within a reaction chamber. While the ways in which embodiments of the disclosure address various issues with conventional assemblies are discussed in more detail below, in general, the disclosure provides assemblies that can detect presence (e.g., missing or out of place) and/or a condition (e.g., breakage) of a lift pin during operation of systems that include such assemblies.

In accordance with exemplary embodiments of the disclosure, a substrate lift assembly is provided. The substrate lift assembly includes a susceptor, a plurality of lift pins extending through a body of the susceptor, a plate, a sensor, and a lift mechanism to move the susceptor relative to the plate. In accordance with examples of these embodiments, the sensor is configured to determine one or more of presence information and condition information associated with one or more (e.g., each) of the lift pins of the plurality of lift pins. In accordance with further examples, the plate includes a plurality of lift pin pads corresponding to each lift pin of the plurality of lift pins. In accordance with further examples, the substrate lift assembly includes a plurality of sensors, including the sensor. In such cases, each of the plurality of sensors can be formed on or within a lift pin pad of the plurality of lift pin pads. The sensor can be or include, for example, a magnetic sensor, an optical sensor, a diffuse sensor, a resistance temperature detector, a linear variable differential transducer, a load cell, a voltmeter, a strain gauge, a piezoelectric device, or the like. In some cases, the one or more sensors can be coupled to a bottom surface of the plate. In some cases, the plate includes an opening or feedthrough and at least a portion of the sensor is within the feedthrough. In accordance with further examples, the assembly includes a controller coupled to one or more of the sensors. The controller can be configured to cease operation of the assembly and/or a reactor system based on the one or more of presence information and condition information associated with each of the lift pins.

In accordance with further examples of the disclosure, a method of determining one or more of a presence and a condition of one or more lift pins is provided. The method can include providing the one or more lift pins within a susceptor; providing a sensor proximate the one or more lift pins; moving the susceptor; and sensing one or more of a presence and a condition of each of the one or more lift pins. The one or more of a presence and a condition can be detected using, for example, a force exerted by the one or more lift pins; a light transmission; a resistance; linear movement of the one or more lift pins; a lift pin pad contact and/or release time associated with each or the one or more lift pins; a voltage; a strain, and/or the like.

In accordance with yet further embodiments of the disclosure, a system is provided. In accordance with examples of the disclosure, a system includes a reaction chamber, a lift assembly (e.g., a lift assembly as described above and elsewhere herein), and a controller. The controller can be configured to move the susceptor and to cease operation of the assembly or system based on one or more of lift pin presence information and lift pin condition information.

All of these embodiments are intended to be within the scope of the disclosure. These and other embodiments will become readily apparent to those skilled in the art from the following detailed description of certain embodiments having reference to the attached figures, the disclosure not being limited to any particular embodiment(s) discussed.

### BRIEF DESCRIPTION OF THE DRAWING FIGURES

While the specification concludes with claims particularly pointing out and distinctly claiming what are regarded as embodiments of the disclosure, the advantages of embodiments of the disclosure may be more readily ascertained from the description of certain examples of the embodiments of the disclosure when read in conjunction with the accompanying drawings.

FIG. 1 illustrates a simplified cross-sectional view of a system, with a substrate in a raised position, in accordance with examples of the disclosure.

FIG. 2 illustrates a simplified cross-sectional view of the system of FIG. 1, with the substrate on a susceptor, in accordance with examples of the disclosure.

FIG. 3 illustrates an assembly in accordance with examples of the disclosure.

FIG. 4 illustrates an assembly in accordance with further examples of the disclosure.

FIGS. 5 and 6 illustrate another assembly in accordance with examples of the disclosure.

FIGS. 7-10 illustrate additional exemplary assemblies in accordance with examples of the disclosure.

FIG. 11 illustrates another assembly in accordance with further examples of the disclosure.

FIG. 12 illustrates yet another assembly in accordance with yet further examples of the disclosure.

FIG. 13 illustrates yet another assembly in accordance with yet further examples of the disclosure.

FIG. 14 illustrates yet another assembly in accordance with yet further examples of the disclosure.

FIG. 15 illustrates yet another assembly in accordance with yet further examples of the disclosure.

FIG. 16 illustrates yet another assembly in accordance with yet further examples of the disclosure.

It will be appreciated that elements in the figures are illustrated for simplicity and clarity and have not necessarily been drawn to scale. For example, the dimensions of some of the elements in the figures may be exaggerated relative to other elements to help improve understanding of illustrated embodiments of the present disclosure.

### DETAILED DESCRIPTION

Although certain embodiments and examples are described below, it will be understood by those in the art that the disclosure extends beyond the specifically disclosed embodiments and/or uses of the disclosure and obvious modifications and equivalents thereof. Thus, it is intended that the scope of the disclosure should not be limited by the particular embodiments described herein.

As described in greater detail below, various details and embodiments of the disclosure may be used in connection with reactor systems used in the manufacture of electronic devices. For example, the assemblies and systems can be used in conjunction with a reactor system with one or more reaction chambers configured for depositing material on a substrate, etching material from a substrate, cleaning a surface of a substrate, and/or treating a surface of a substrate.

The inventors recognized the importance of sensing or detecting one or more of presence information and condition (e.g., breakage or damage) information associated with lift pins that are used to raise a substrate from a susceptor surface. The presence information and/or condition information can be used to alert an operator of a reactor system to address the issue and/or to cease operation of an assembly and/or a system.

As used herein, the term substrate may refer to any underlying material or materials that may be used to form, or upon which, a device, a circuit, or a film may be formed. A substrate can include a bulk material, such as silicon (e.g., single-crystal silicon), other Group IV materials, such as germanium, or compound semiconductor materials, such as GaAs, and can include one or more layers overlying or underlying the bulk material. Further, the substrate can include various topologies, such as recesses, lines, and the like formed within or on at least a portion of a layer of the substrate.

Further, in this disclosure, any two numbers of a variable can constitute a workable range of the variable, and any ranges indicated may include or exclude the endpoints. Additionally, any values of variables indicated (regardless of whether they are indicated with “about” or not) may refer to precise values or approximate values and include equivalents, and may refer to average, median, representative, majority, or the like. Further, in this disclosure, the terms “including,” “constituted by” and “having” can refer independently to “typically or broadly comprising,” “comprising,” “consisting essentially of,” or “consisting of” in some embodiments. The term comprising includes consisting essentially of and consisting of. “Substantially” can mean within about +10 or +5 relative or absolute percent. In this disclosure, any defined meanings do not necessarily exclude ordinary and customary meanings in some embodiments.

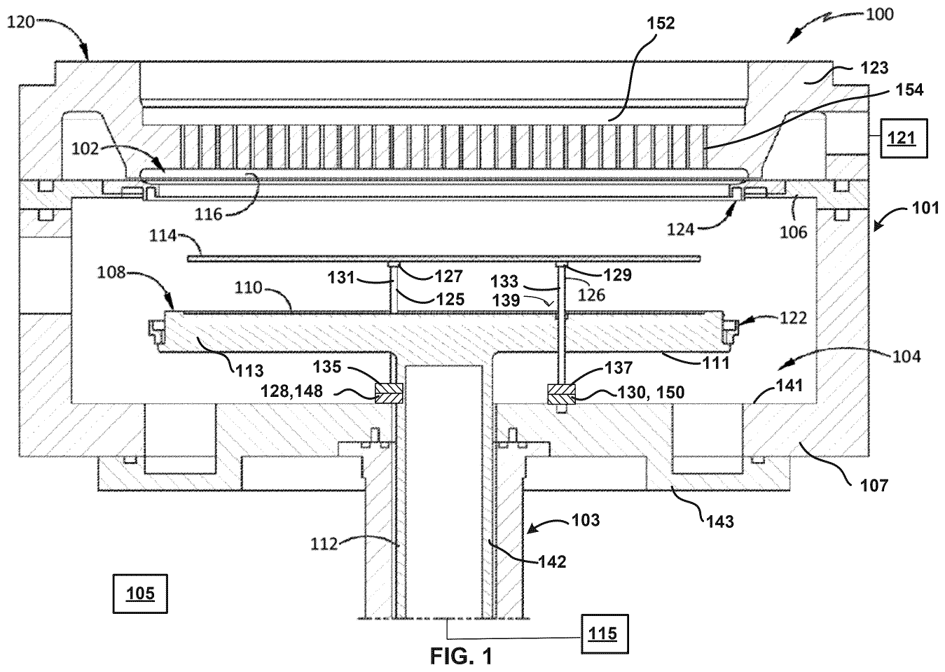

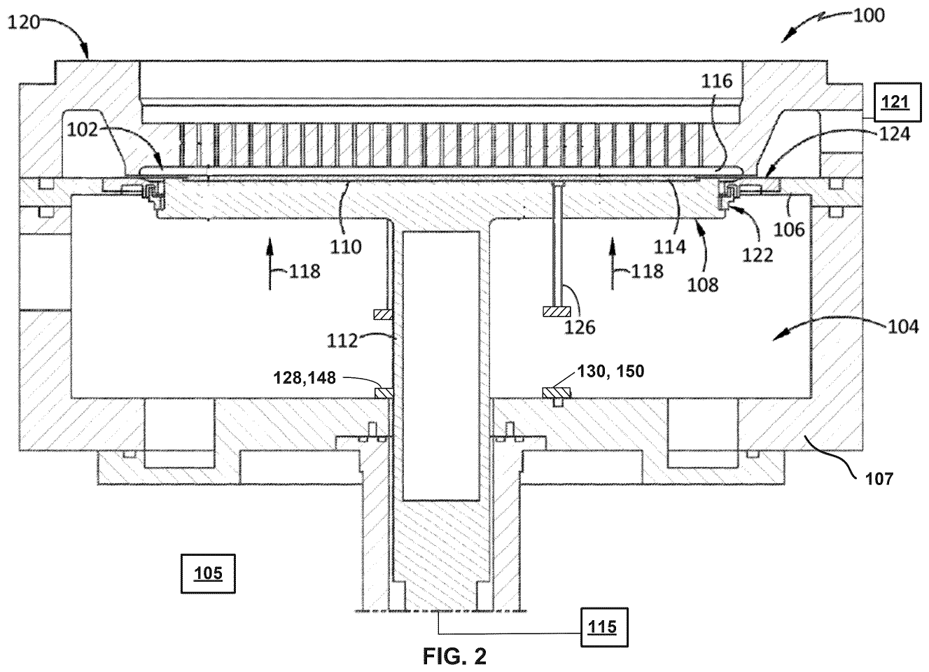

Turning now to the figures, FIGS. 1 and 2 illustrate an exemplary system 100 in accordance with examples of the disclosure. More particularly, FIG. 1 illustrates system 100 in a load/unload configuration and FIG. 2 illustrates system 100 in a processing position.

In the illustrated examples, system 100 includes a reactor or reaction chamber 101, including an upper chamber 102 and a lower chamber 104; a separation plate 106 between upper chamber 102 and lower chamber 104; a substrate lift assembly 103, a controller 105, a gas distribution assembly 120, and an exhaust source 121.

Reaction chamber 101 can be or include a reaction chamber suitable for gas-phase reactions. Reaction chamber 101 can be formed of suitable material, such as quartz, metal, or the like, and can be configured to retain one or more substrates for processing. System 100 can include any suitable number of reaction chambers 101 and can optionally include one or more substrate handling systems. Reaction chamber 101 can be configured as a CVD reactor, a cyclical deposition process reactor (e.g., a cyclical CVD reactor), an ALD reactor, a PEALD reactor, or the like, any of which may include plasma apparatus, such as direct and/or remote plasma apparatus. System 100 can be used to process substrates. In general, processing of substrates occurs within upper chamber 102, while substrate loading and unloading occurs within lower chamber 104.

Separation plate 106 can be configured as a substantially annular ring. In accordance with examples of the disclosure, separation plate 106 can be used to isolate or provide a tortuous path for gas between upper chamber 102 and lower chamber 104 during substrate processing.

Substrate lift assembly 103 includes a susceptor 108; a plurality of lift pins 125, 126; a plate 107 (which can form an interior lower surface of the reaction chamber); one or more sensors 128, 130; a lift mechanism 112, such as a (e.g., vertically) movable elevator. As described in more detail below, one or more sensors 128, 130 can be used to determine one or more of presence information and condition information associated with each lift pin 125, 126 of a plurality of lift pins. In some cases, system 100 includes a plurality of lift pin pads 148, 150 corresponding to each lift pin 125, 126 of the plurality of lift pins. As discussed in more detail below, lift pin pads 148, 150 can be formed on plate 107, be integral with plate 107, or be a raised section of plate 107. In some cases, one or more sensors 128, 130 can be incorporated in a respective lift pin pad 148, 150. Alternatively, as described below, sensors 128, 130 may be separate from pin pads 148, 150. In these cases, a system may include sensors 128, 130 and not include lift pin pads 148, 150.

Susceptor 108 includes a susceptor top surface 110, a susceptor bottom surface 111, and a susceptor body 113 spanning therebetween. Susceptor body 113 can be formed of any suitable material, such as aluminum, aluminum alloys, stainless steel, or a ceramic, such as aluminum nitride. A thickness of susceptor body 113 between top surface 110 and bottom surface 111 can be between about 1 and about 22 mm or between about 16 and about 22 mm. A substrate 114 may be positioned on top surface 110 and may be located in a processing region 116 when susceptor 108 is moved upwards in the direction of arrows 118 as shown in FIG. 2. In some embodiments of the disclosure, a first sealing member 122 may be positioned on and removable from susceptor 108, while a second sealing member 124 may be positioned between upper chamber 102 and lower chamber 104. In some embodiments, second sealing member 124 may be positioned to rest at least partially on the interface plate 106 or may be connected to the interface plate 106 or any other suitable portion of the reaction chamber 101.

Lift pins 125, 126 extend through body 113 of susceptor 108. As illustrated, each lift pin 125, 126 can include a top section or head 127, 129, a lift pin body 131, 133, and a bottom section or base 135, 137. Lift pin body 131, 133 spans between the respective head 127, 129 and base 135, 137. In the illustrated example, a cross section of head 127, 129 and a cross section of base 135, 137 are greater than a cross section of the lift pin body 131, 133. In some cases, only a cross section of heads 127, 129 may be greater than the cross section of the lift pin body 131, 133. As illustrated, top section/head 127, 129 can be received within a recess 139 within susceptor 108, such that a top of top section 127, 129 is at or below surface 110 during substrate processing. Bottom section/base 135, 137 can be weighted and/or functionalized as described in more detail below. A number of lift pins 125, 126 can vary. However, in accordance with examples of the disclosure, substrate lift assembly 103 includes a plurality of lift pins. The plurality can include, for example, three or more lift pins.

When used in connection with lift pin pads 148, 150, lift pin 125, 126 can be relatively short. For example, a height of lift pins 125, 126 from a top of head 127, 129 to a bottom of base 135, 137 or to a bottom of body 131, 133 can be between about 45 mm and about 75 mm or between about 50 and 70 mm. A cross-sectional dimension of head 127, 129 can be between about 2 mm and about 6 mm or between about 2 mm and about 4 mm. A cross-sectional dimension of base 135, 137 can be between about 15 mm and about 30 mm or between about 20 mm and about 25 mm.

Lift pins 125, 126 can be formed of any suitable material. For example, lift pins 125, 126 can be formed of stainless steel or ceramic material. In some cases, lift pins 125, 126 can be formed of high flexural strength and fracture-resistant materials, such as Sialon (ceramic alloys based on the elements silicon (Si), aluminum (Al), oxygen (O) and nitrogen (N)), Si₃N₄, SiC, or the like.

Plate 107 includes a plate top surface 141 and a plate bottom surface 143. Plate top surface 141 can be proximate (e.g., directly opposite) susceptor bottom surface 111. Plate bottom surface 143 is opposite plate top surface 141.

When included, pin pads 148, 150 can have a height H of about 75 mm to about 125 mm or about 80 mm to about 120 mm. As noted above, in some cases, pin pads 148, 150 include a sensor, such as a sensor described herein. In other cases, pin pads do not include a sensor, but may be present and used in connection with other sensors described herein. Use of pin pads 148, 150 can be advantageous, because pin pads 148, 150 can allow for shorter lift pins 125, 126, which can mitigate risk of breakage of lift pins 125, 126.

Sensors 128, 130 can be generally configured to determine one or more of presence information and condition information associated with each lift pin 125, 126 of a plurality of lift pins. As explained in greater detail below, sensors 128, 130 can be configured in a variety of ways. In some cases, system 100 can include one sensor for each lift pin 125, 126. In other configurations, system 100 includes two or more sensors for each lift pin 125, 126. Further, as described below, in some cases, sensors 128, 130 reside within reaction chamber 101/lower chamber 104; in other cases, sensors 128, 130 reside outside reaction chamber 101/lower chamber 104.

When pin pads 148, 150 include a sensor (e.g., sensor 128, 130), sensor 128, 130 can be or include, for example, a magnetic sensor, a capacitive sensor, an optical sensor (such as sensor 302 described below), a load cell, a voltmeter, a piezoelectric device, or other sensor, such as another sensor described here.

In accordance with examples of the disclosure, base 135, 137 can include a magnet or magnetic material. In this case, sensor 128, 130 can include a magnet, and a force between sensor 128, 130 and corresponding lift pin 125, 126 can be used to determine one or more of lift pin condition (e.g., stuck or broken) and/or lift pin position information. Alternatively, base 135, 137 can include conductive material and sensor 128, 130 can use a change in capacitance to determine one or more of lift pin condition and/or lift pin position information.

In accordance with other examples, sensor 128, 130 can be or include a load cell. Use of a load cell sensor (e.g., as part of or separate from pin pads 148, 150) can allow determination of whether two or more (e.g., all) of lift pins 125, 126 are being lifted by the susceptor at substantially the same time. As the pins are being lifted, the load cells will return a value of zero, no load. If the load cells all return the value of zero within a given threshold (e.g., less than about 2 seconds or less than about 3 seconds) there is high confidence that none of the lift pins are stuck. In the event a lift pin is stuck, we would see that a load cell/sensor returns a value of zero earlier than the other load cells/sensor. Chances of all lift pins 125, 126 being stuck at the same time is very low and all three lift pins 125, 126 being stuck at substantially the same height is even lower.

In some cases, the sensor can be or include a piezoelectric device. For example, a load cell as described above, can include a piezoelectric device.

In accordance with further examples of the disclosure, an electromagnetic field is applied to pin pads 148, 150 and a voltage is measured using sensors 128, 130 to determine whether lift pins 125, 126 are at desired positions/distances from respective sensors 128, 130. Sensors 128, 130 can, in such cases, be or include a voltmeter. During operation, as lift pins 125, 126 are lifted by susceptor 108, a voltage will be induced. The induced voltage can be based on a distance of lift pin 125, 126 (e.g., base 135, 137) from respective sensors 128, 130. In an ideal scenario, one would expect the same output from all sensors 128, 130 as lift pins 125, 126 move relative to the sensors. If there was a deviation from our baseline data, it would indicate that that a pin is stuck or damaged.

Lift mechanism 112 can include, for example, a shaft 142 and a motor 115. Motor 115 can be used to move shaft 142 and susceptor 108 from a load/unload position as illustrated in FIG. 1 to a processing position, as illustrated in FIG. 2.

Gas distribution assembly 120 can be or include a showerhead assembly. By way of example, gas distribution assembly 120 can include a showerhead plate 123 that includes a plenum region 152 and a plurality of holes 154.

Exhaust source 121 can include, for example, one or more vacuum sources. Exemplary vacuum sources include one or more dry vacuum pumps and/or one or more turbomolecular pumps.

Controller 105 can be configured to perform operations of system 100 and substrate lift assembly 103. Further, controller 105 can be wired to or wirelessly connected to one or more sensors, such as sensors 128, 130 described herein. As noted above, controller 105 can be configured to effect action (e.g., send a warning signal and/or cease operation) based on the one or more of presence information and condition information associated with each of the lift pins. In some cases, controller 105 can be or include a programmable logic controller as described herein.

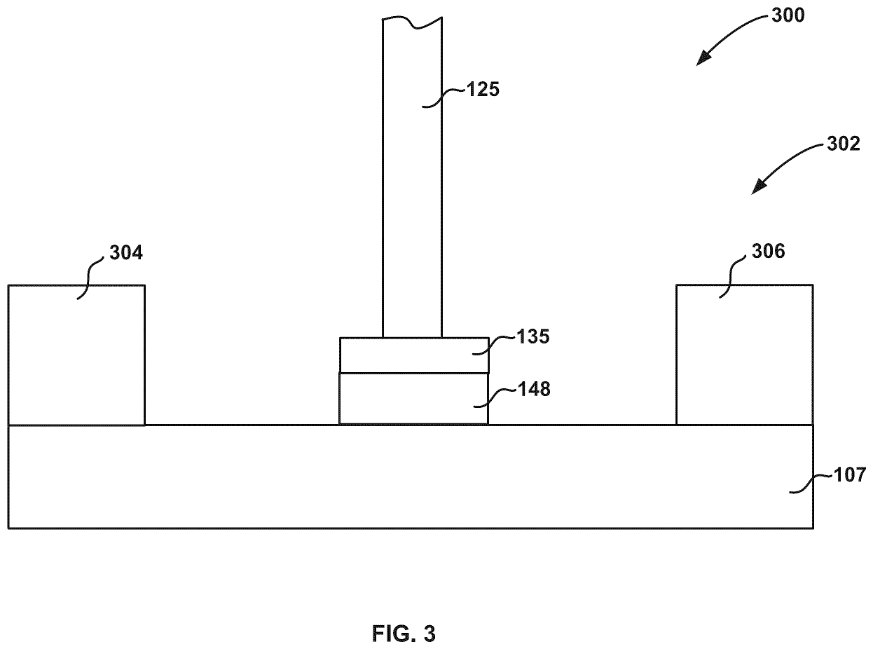

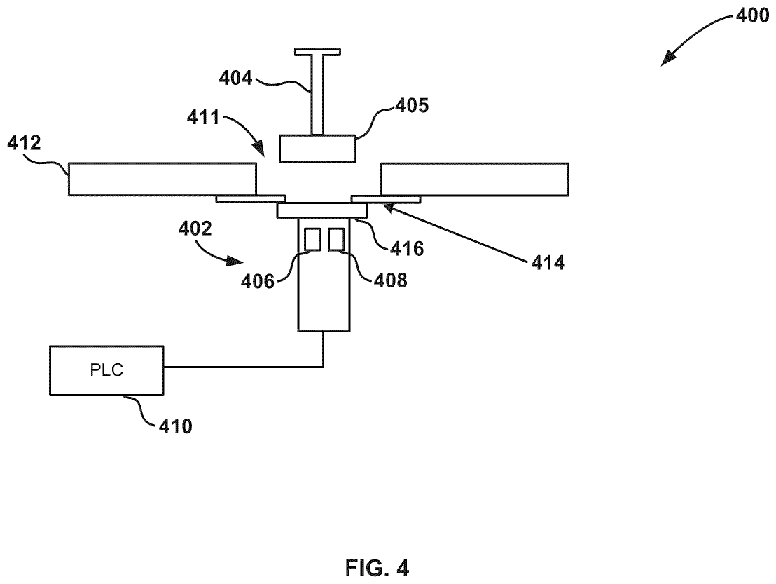

FIG. 3 illustrates a substrate lift assembly 300 in accordance with examples of the disclosure. Although not illustrated, assembly 300 can include a susceptor, such as susceptor 108. Assembly 300 includes lift pin 125, (optionally) lift pin pad 148, plate 107, and a sensor 302 that includes an emitter 304 and a detector 306. Sensor 302 can be an optical sensor. Emitter 304 and detector 306 can be configured to detect a presence or absence of lift pin 125—e.g., when susceptor 108 is in a load/unload position. In accordance with examples of the disclosure, emitter 304 is a light emitter, such as a laser. Detector 306 can be a light detector, such as a laser light detector. Sensor 302 can be configured to determine whether lift pin 125 is between emitter 304 and detector 306-either when lift pin 125 should be present (e.g., during a load/unload process), or when lift pin 125 should not be present (e.g., during processing of substrate 114). In accordance with examples of the disclosure, at least one sensor 302 (i.e., one emitter 304 and one detector 306) is provided for each lift pin of a system, such as system 100. As illustrated, sensor 302 is within reaction chamber 101/lower chamber 104. Assembly 300 can also include a feedthrough and/or a flange as described below in connection with FIGS. 4, 8, 11, and 12.

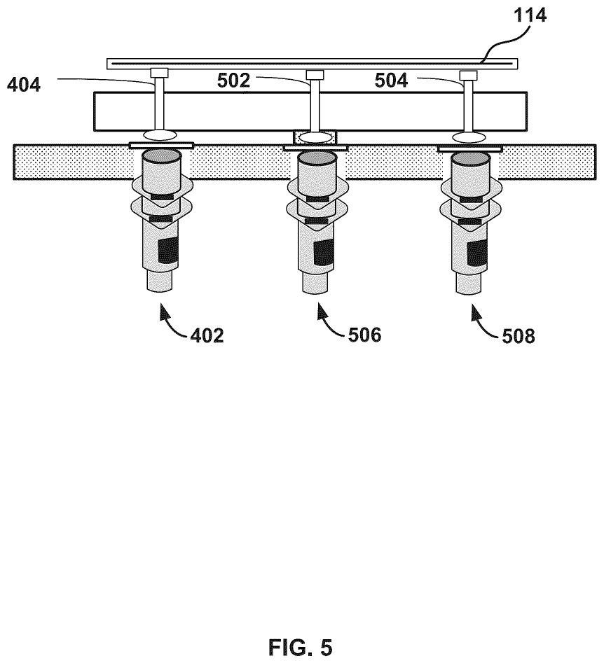

FIGS. 4-6 illustrate substrate lift assembly 400 in accordance with examples of the disclosure. Substrate lift assembly 400 includes lift pin 404, a plate 412, and one or more sensors 402—e.g., one or more sensors 402, 506, 508 for each lift pin 404, 502, 504, which can be the same or similar to lift pins 125, 126. Lift pin 404 is illustrated with a base 405, which can be the same or similar to base 135 described above. In accordance with examples, base 405 can be or include reflective material, such as polished stainless steel, a chrome finish, or other material with a mirror finish.

Sensors 402, 506, 508 can be or include a diffuse sensor, which can include background suppression. Sensors 402, 506, 508 can be optical sensors. As illustrated in FIG. 4, sensor 402 can includes a light emitter 406 and a light detector 408. Light emitter 406 can be or include, for example, a light-emitting diode. Light detector 408 can be or include, for example, a an infrared (IR) detector, a red light detector, a photo detector, or a reflector/diffuse sensor. As illustrated, an optical axis for light emitter 406 and an optical axis for light detector 408 can be offset. In operation, light can be emitted toward lift pin base 405 and reflect back to light detector 408. Information received by light detector 408 can be transmitted to programmable logic controller 410 to determine a presence, lack of presence, or distance of base 405 relative to plate 412 or sensor 402. In operation, when the distance of base 405 changes, a position where the light is received on the receiver element changes. This change is converted into a displacement reading by PLC 410. In accordance with particular examples, when lift pin 404 approaches or leaves sensor 402, sensor 402 detects the displacement of lift pin 404 and provides an output to PLC 410, which generates a signal when lift pin 404 is determined to be stuck or otherwise not in a proper position or condition.

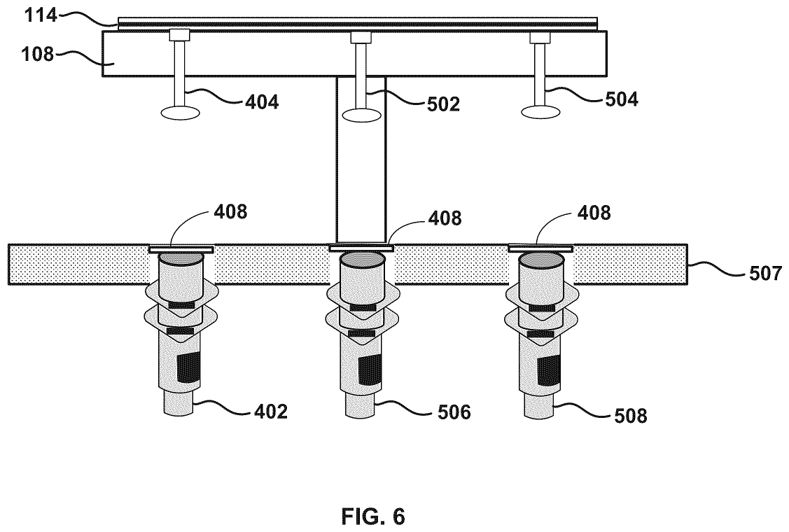

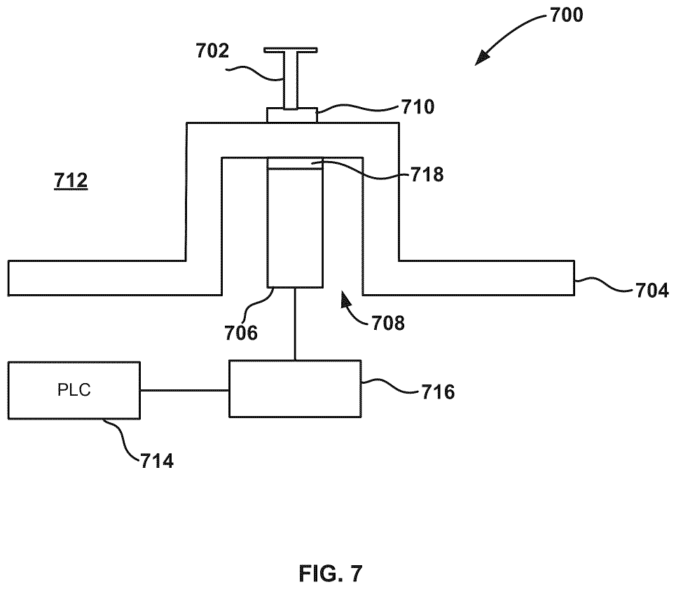

In the example illustrated in FIGS. 4-6, sensors 402, 506, 508 are positioned exterior of a reaction chamber, such as reaction chamber 101/lower chamber 104. FIG. 4 illustrates sensor 402 entirely outside a reaction chamber (e.g., reaction chamber 101) or plate 412 and FIGS. 6 and 7 illustrate sensors 402, 506, 508 partially within a plate 507 (which can be the same or similar to plate 107). Thus, lift pin condition can be determined non-invasively, from outside the reaction chamber. In this case, a flange 414 can be used to couple a transparent window 416 to an opening 411 in a plate 412, which can otherwise be the same or similar to plate 107. Window 416 can be formed of, for example, quartz.

FIG. 7 illustrates another substrate lift assembly 700 in accordance with examples of the disclosure. Substrate lift assembly 700 includes a lift pin 702, a plate 704, and one or more sensors 706.

Lift pin 702 can be the same or similar to lift pin 125 described above. In the illustrated example, lift pin 702 includes a base 710. Base 710 can be or include a magnet, such as a real or permanent magnet.

Plate 704 can be the same or similar to plate 107, described above, except plate 704 can optionally include a raised section or area 708, which can receive at least a portion of sensor 706. In some cases, sensor 706 is coupled to plate 704 within raised section 708. Raised section 708 can be the same or similar to pin pad 148 described above.

Sensor 706 can be or include a magnetic proximity sensor. Magnetic proximity sensors detect magnetic fields and are capable of detecting permanent magnets through non-ferromagnetic materials (e.g., non-ferrous metals, such as aluminum, stainless steel, quartz, and the like). During operation of substrate lift assembly 700, when lift pin 702 approaches sensor 706, sensor 706 detects a magnetic field and outputs a signal to a programmable logic controller 714 optionally through an amplifier 716. Amplifier 716 can amplify a signal from sensor 706 to PLC 714. PLC 714 can, in turn, produce and/or send a signal indicative of a distance, presence, and/or condition of lift pin 702. In some cases, the signal can be generated or transmitted when a determined distance for an operating condition is outside a preset value. In accordance with examples of the disclosure, lift assembly 700 includes one sensor for each lift pin.

In the illustrated example, sensor 706 is exterior of a reaction chamber—i.e., sensor 706 is positioned on an outside surface of plate 704 relative to lower chamber 712, which can be the same or similar to lower chamber 104.

In the illustrated example, lift assembly 700 includes an insulating material 718 interposed between (e.g., directly in contact with one or more of) plate 704 and sensor 706. Insulating material 718 can mitigate heat transfer between lower chamber 712 and sensor 706. When sensor 706 is exterior of the reaction chamber, insulating material 718 can include plastic (e.g., PTFE) or the like.

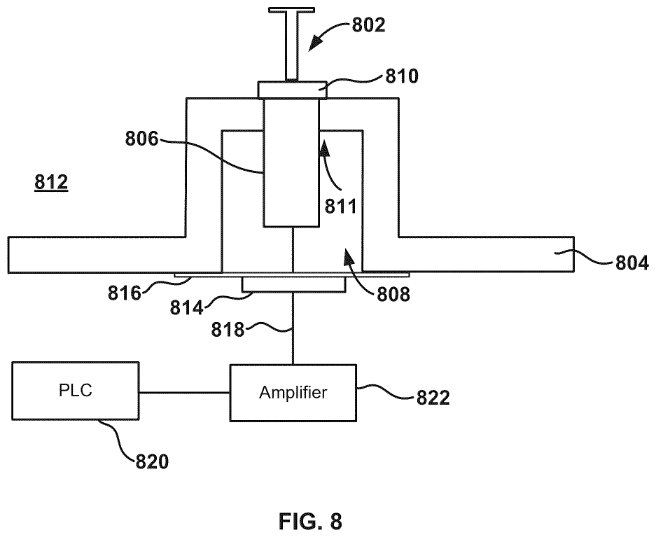

FIG. 8 illustrates another substrate lift assembly 800 in accordance with examples of the disclosure. Substrate lift assembly 800 is similar to substrate lift assembly 700, except substrate lift assembly 800 includes a sensor 806 that is exposed to an interior region of a reactor, such as a lower chamber 812, of a reactor chamber. Similar to substrate lift assembly 700, substrate lift assembly 800 includes a lift a pin 802, a plate 804, and one or more sensors 806. Lift pin 802 can be the same or similar to lift pin 702 and sensor 806 can be the same or similar to sensor 706.

Plate 804 can be similar to plate 704, except plate 804 includes a raised section 808 that includes an opening 811 therein. At least a portion of sensor 706 can be inserted into opening 811, such that a portion of sensor 806 is exposed to an interior portion (e.g., a lower chamber 812) of the reactor.

A feedthrough 814 and a flange 816 can be used to seal sensor 806 from ambient conditions, while allowing a signal wire 818 to connect to PLC 820 and optionally amplifier 822. PLC 820 and amplifier 822 can be the same or similar to PLC 714 and amplifier 716 described above.

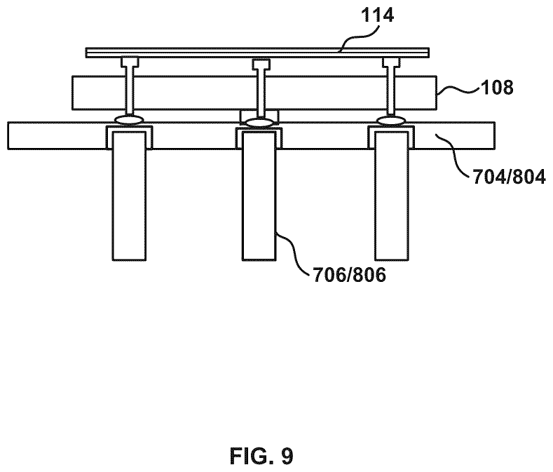

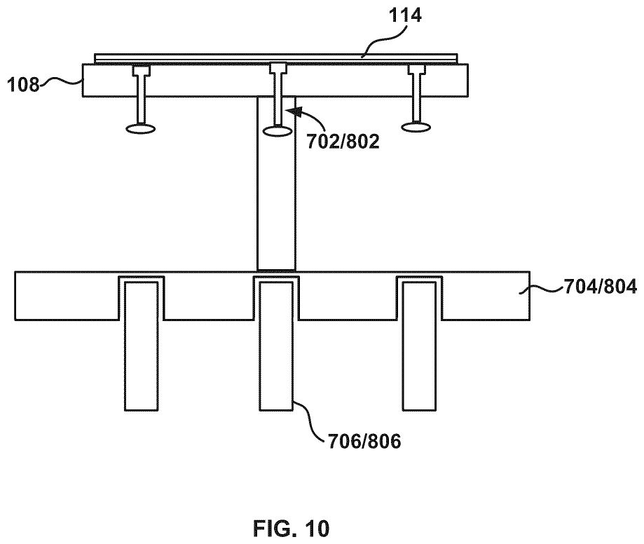

FIGS. 9 and 10 illustrate operation of substrate lift assemblies 700 and 800. FIG. 9 illustrates assemblies 700, 800 in a load/unload position with substrate 114 in a raised position. In this case, base 710, 810 can contact or be near (a distance from) sensor 706, 806. The distance can be based on the type of sensor that is used. Some sensors will have shorter sensing fields than others. FIG. 10 illustrates assemblies 700, 800 in a processing position with substrate 114 in a raised position.

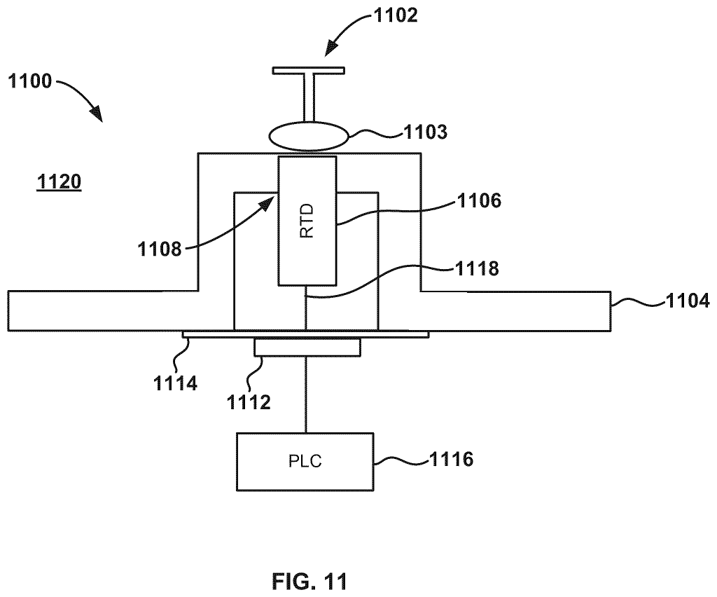

FIG. 11 illustrates another substrate lift assembly 1100 in accordance with examples of the disclosure. Assembly 1100 includes lift pin 1102, plate 1104, and sensor 1106.

Lift pin 1102 can be as described above. In accordance with examples of the disclosure, lift pin 1102 includes a base 1103. Base 1103 can be formed of a metal, such as stainless steel.

Plate 1104 can be the same or similar to base 810 described above. As illustrated, plate 1104 includes an opening 1108, in which at least a portion of sensor 1106 is disposed. In accordance with examples of the disclosure, at least a portion of sensor 1106 is exposed to an interior space 1120 of a reaction chamber.

Sensor 1106 is or includes a (e.g., platinum) resistance temperature detector (RTD). Sensor 1106 can have, for example, a resistance of 1000 at 0° C. A resistance of sensor 1106 changes with temperature. Thus, as a temperature changes (e.g., increases), the resistance of the RTD also changes (e.g., increases). Therefore, by measuring sensor 1106 resistance, one can determine the temperature. During operation, when lift pin 1102 contacts or is proximate sensor 1106, sensor 1106 detects a change in temperature. The change in temperature can be used to detect presence and/or condition of lift pin 1102 and provide a signal.

A feedthrough 1112 and a flange 1114 can be used to seal sensor 1106 from ambient conditions. A wire 1118 from sensor 1106 to a programmable logic controller 1116 can be fed through feedthrough 1112.

Programmable logic controller 1116 can be similar to other PLCs described herein. For example, PLC 1116 can receive a signal from sensor 1106 (and optionally an amplifier) and determine lift pin 1102 condition and/or presence and send a corresponding signal or perform an operation as described herein.

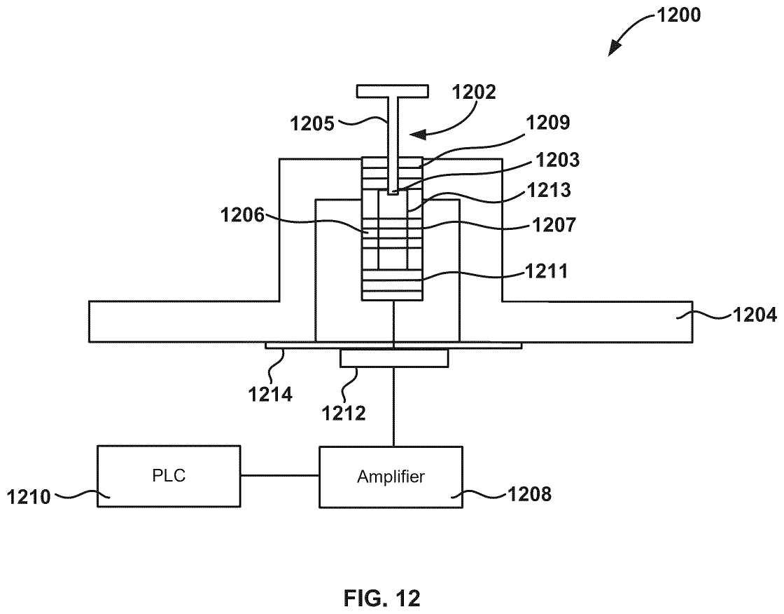

FIG. 12 illustrate another substrate lift assembly 1200 in accordance with examples of the disclosure. Substrate lift assembly 1200 is similar to substrate lift assembly 1100, except substrate lift assembly 1200 includes a lift pin 1202, a sensor 1206, an amplifier 1208, and a programmable logic controller 1210. Substrate lift assembly 1200 also includes a plate 1204, a feedthrough 1212 and a flange 1214. Feedthrough 1212 and flange 1214 can be the same or similar to feedthrough 1112 and flange 1114 described above. Plate 1204 can be the same or similar to plate 1104 described above.

Lift pin 1202 can be the same or similar to lift pin 125 described above. In some cases, lift pin 1202 includes a base 1203; in some cases, base 1203 may have substantially a same diameter as a diameter of a body 1205. In accordance with examples of the disclosure, lift pin 1202 and particularly lift pin body 1205 is or comprises stainless steel or other conductive material.

Sensor 1206 is or includes a linear variable differential transducer (LVDT) sensor. Sensor 1206 is configured to convert linear movement of lift pin 1202 into a variable corresponding to an electrical signal proportional to such movement. An amount or magnitude of displacement can be proportional to a differential output of sensor 1206. The more the output voltage, the more will be the displacement of the object. Signal from sensor 1206 can be used to detect lift pin 1202 presence and/or condition information.

In the illustrated example, sensor 1206 includes primary windings 1207, secondary windings 1209, 1211, and a (e.g., soft) iron core 1213. Iron core 1213 can receive at a portion of lift pin 1202. Using, for example, primary windings 1207, secondary windings 1209, 1211, and soft iron core 1213, sensor 1206 can measure a position of lift pin 1202 in real time and provide a signal to amplifier 1208 and PLC 1210 to determine presence and/or condition information corresponding to lift pin 1202.

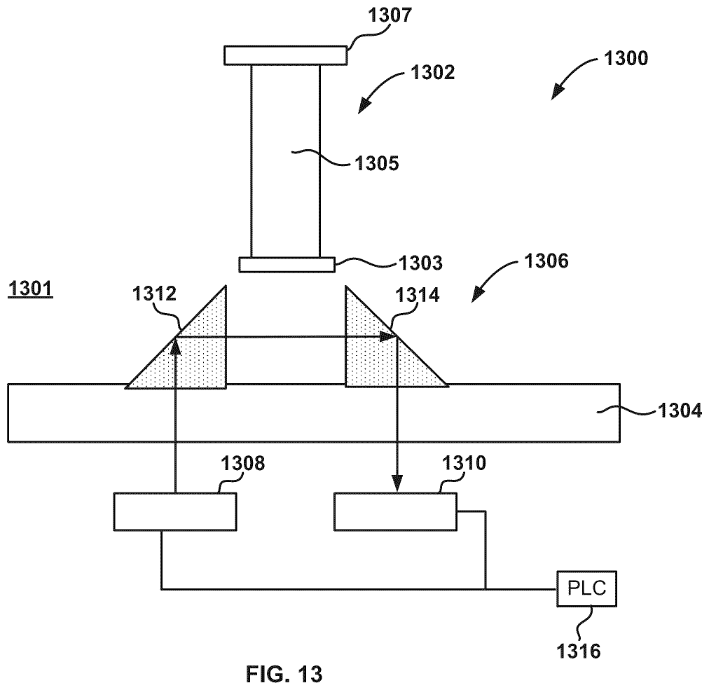

FIG. 13 illustrates another substrate lift assembly 1300 in accordance with examples of the disclosure. Substrate lift assembly 1300 is similar to substrate lift assembly 300, except substrate lift assembly 1300 includes a sensor 1306, with components inside and outside of a reaction chamber having a lower chamber 1301.

In more detail, substrate lift assembly 1300 includes a lift pin 1302, a plate 1304, and a sensor 1306. Lift pin 1302 can be the same or similar to lift pin 125. Lift pin 1302 can include a lift pin head 1307, optionally a lift pin base 1303, and a lift pin body 1305, such as those lift pin components described above in connection with FIGS. 1 and 2.

Plate 1304 can be or include material that is transparent (e.g., greater than 80% or 90% transparent) to light emitted and/or detected by sensor 1306. By way of example, plate 1304 can be or include quartz material, which may form a window in, for example, plate 107 described above.

Sensor 1306 includes a source 1308, a detector 1310, a first prism 1312, and a second prism 1314. Sensor 1306 can be an optical sensor. In operation, light emitted from source 1308 is directed toward first prism 1312, which directs light toward second prism 1314, which, in turn, directs the light toward detector 1310.

Source 1308 can be or include, for example, a light source, such as a laser. Detector 1310 can detect light of the wavelength(s) emitted by source 1308. Detector 1310 is electrically coupled to a programmable logic controller 1316 to provide a signal indicative of lift pin 1302 presence and/or condition to programmable logic controller 1316.

In the illustrated examples, prisms 1312 and 1314 are configured to bend light at, for example, about 90 degrees. A distance between prisms 1312 and 1314 can be, for example, between about 3 mm (e.g., a diameter of a pin) and about a diameter or other cross sectional measurement of an inside of the reaction chamber, for example, about 350 to about 400 mm.

PLC 1316 can be coupled to source 1308 and/or detector 1310, such that PLC 1316 can provide power to source 1308 and/or receive a signal from detector 1310. In some cases, PLC 1316 can be configured to continually monitor a signal from 1310 and correlate a received signal with an expected position of lift pin 1302.

Although illustrated with one source 1308 and one detector 1310 for a lift pin 1302, in some cases, an assembly can include multiple lift pins for each source and/or detector. In such cases, a plurality of prisms, such as prisms 1312, 1314, may be in series.

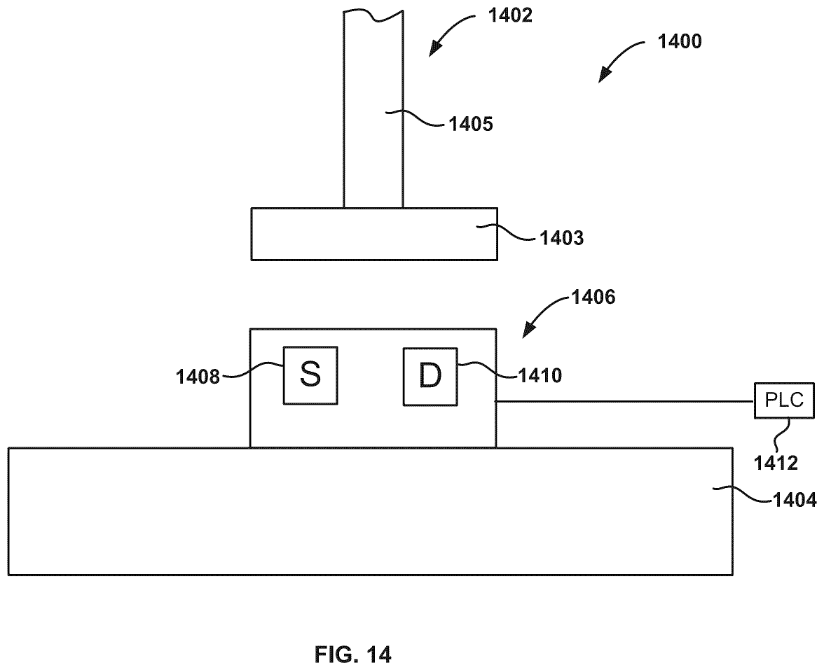

FIG. 14 illustrates another substrate lift assembly 1400 in accordance with additional examples. Substrate lift assembly 1400 includes a lift pin 1402, plate 1404, and sensor 1406.

Lift pin 1402 includes a lift pin body 1405 and a lift pin base 1403. Lift pin 1402 can be the same or similar to lift pin 125 described above.

Plate 1404 can be the same or similar to plate 107 described above. Sensor 1406 can be (e.g., directly) mounted onto plate 1404.

In accordance with examples of the disclosure, sensor 1406 is or includes a (e.g., light) source 1408 and a (e.g., light) detector 1410. In accordance with examples of the illustrated embodiment, lift assembly 1400 is configured to determine lift pin presence and/or condition information by measuring a distance between sensor 1406 and lift pin 1402. More specifically, sensor 1406 can be configured to measure a time for a signal emitted from source 1408 to reflect from lift pin 1402 (or not) and return to detector 1410.

Sensor 1406 can be coupled to a programmable logic controller 1412, which can receive a signal from sensor 1406 to determine condition and/or presence information associated with lift pin 1402. For example, in some cases, PLC 1412 can determine a distance of lift pin 1402 from sensor 1406 and correlate the distance with an expected distance of lift pin 1402. If the distance is above or below an expected value, PLC 1412 can generate and send a signal to cease operation of assembly 1400 and/or a system, such as a system described herein.

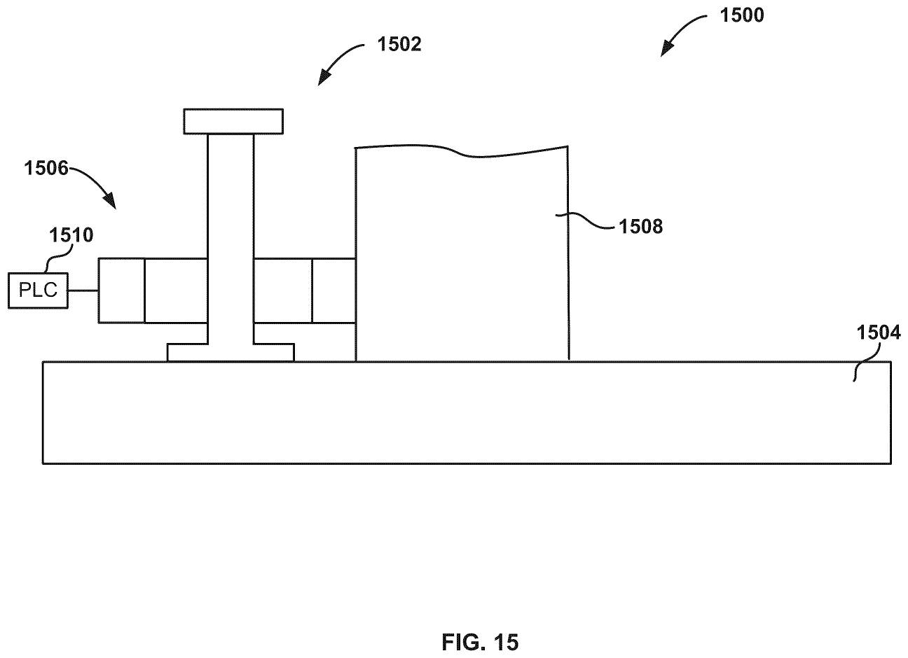

FIG. 15 illustrates another substrate lift assembly 1500 in accordance with additional embodiments. Substrate lift assembly 1500 includes a lift pin 1502, a plate 1504, a sensor 1506, and a shaft 1508.

Lift pin 1502 can be the same or similar to lift pin 125. Similarly, plate 1504 can be the same or similar to plate 107.

Sensor 1506 is coupled to (e.g., moveable) shaft 1508. Shaft 1508 can be the same or similar to shaft 142. With reference to FIGS. 1 and 15, as shaft 1508/142 moves, lift pin 1502 can move within a susceptor—e.g., from a raised load/unload position to a lowered processing position. Sensor 1506 can include an emitter and detector as described above in connection with, for example, FIG. 3 or can include another suitable sensor, such as another sensor described herein. Sensor(s) 1506 can be coupled to a programmable logic controller to determine the presence, distance, and/or condition information and to send a corresponding signal to cease operation of assembly 1500 or a system including such assembly.

In some cases, assembly 1500 can include two or more sensors 1506 for one or more lift pins 1502 to determine a location and/or condition of lift pin 1502.

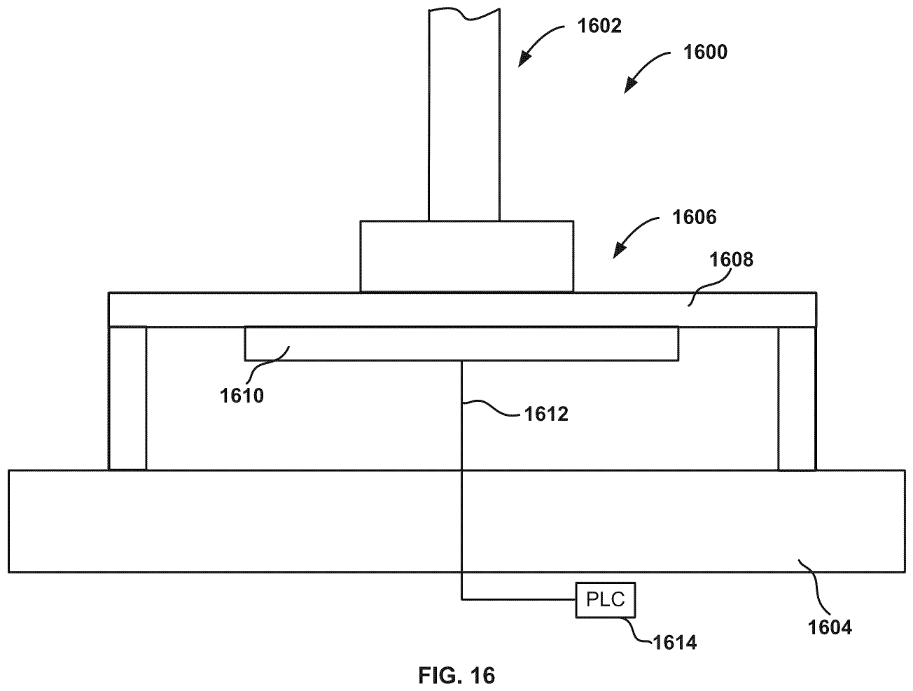

FIG. 16 illustrates yet another substrate lift assembly 1600 in accordance with further exemplary embodiments. Substrate lift assembly 1600 includes a lift pin 1602, a plate 1604, and a sensor 1606 on or within an opening of plate 1604.

Lift pin 1602 can be the same or similar to lift pin 125. Similarly, plate 1604 can be the same or similar to plate 107. Although not separately illustrated, substrate lift assembly 1600 can suitably include a flange and a feedthrough, such as those described above in connection with FIG. 4.

Sensor 1606 can be or include a strain gauge. In some cases, sensor 1606 can be or form part of a lift pin pad, such as a lift pin pad described herein. In the illustrated example, sensor 1606 includes a sensor plate 1608 and a strain gauge 1610 (e.g., directly) attached to sensor plate 1608—e.g., using an adhesive. One or more wires 1612 from strain gauge 1610 can be fed through a feedthrough and flange as described above. A signal from strain gauge 1610 can be transmitted to a programmable logic controller 1614 to determine a presence (or not) of lift pin 1602 and/or a condition of lift pin 1602. For example, PLC 1614 can compare an expected strain and a measured strain to determine whether lift pin 1602 is stuck (e.g., within a susceptor), broken, or missing.

In accordance with further embodiments of the disclosure, a method is provided. In accordance with aspects of these embodiments, a method of determining one or more of a presence and a condition of one or more lift pins includes providing the one or more lift pins within a susceptor; providing a sensor proximate the one or more lift pins; moving the susceptor; and determining (i.e., sensing) one or more of a lift pin presence, distance (e.g., from a sensor), and condition (e.g., stuck or broken). The step of determining can include measuring a force exerted by the one or more lift pins, a light transmission, a resistance, a linear movement of the one or more lift pins, a lift pin pad contact and/or release time associated with each or the one or more lift pins, a voltage, a strain, or the like. For example, the step of determining or measuring can include emitting light and detecting the presence or absence of the light. In some cases, the step of determining or measuring includes emitting light and measuring an amount of the light or an amount of time to receive reflected light. In other cases, the step of determining or measuring includes measuring a magnetic force. Other examples of determining lift pin condition, distance, and/or presence are described above.

Benefits, other advantages, and solutions to problems have been described herein with regard to specific embodiments. However, the benefits, advantages, solutions to problems, and any elements that may cause any benefit, advantage, or solution to occur or become more pronounced are not to be construed as critical, required, or essential features or elements of the disclosure.

Reference throughout this specification to features, advantages, or similar language does not imply that all of the features and advantages that may be realized with the present disclosure should be or are in any single embodiment of the invention. Rather, language referring to the features and advantages is understood to mean that a specific feature, advantage, or characteristic described in connection with an embodiment is included in at least one embodiment of the subject matter disclosed herein. Thus, discussion of the features and advantages, and similar language, throughout this specification may, but do not necessarily, refer to the same embodiment.

Furthermore, the described features, advantages, and characteristics of the disclosure may be combined in any suitable manner in one or more embodiments. One skilled in the relevant art will recognize that the subject matter of the present application may be practiced without one or more of the specific features or advantages of a particular embodiment. In other instances, additional features and advantages may be recognized in certain embodiments that may not be present in all embodiments of the disclosure. Further, in some instances, well-known structures, materials, or operations are not shown or described in detail to avoid obscuring aspects of the subject matter of the present disclosure. No claim element is intended to invoke 35 U.S.C. 112 (f) unless the element is expressly recited using the phrase “means for.”

The scope of the disclosure is to be limited by nothing other than the appended claims, in which reference to an element in the singular is not intended to mean “one and only one” unless explicitly so stated, but rather “one or more.” It is to be understood that unless specifically stated otherwise, references to “a,” “an,” and/or “the” may include one or more than one and that reference to an item in the singular may also include the item in the plural. Further, the term “plurality” can be defined as “at least two.” As used herein, the phrase “at least one of,” when used with a list of items, means different combinations of one or more of the listed items may be used and only one of the items in the list may be needed. The item may be a particular object, thing, or category. Moreover, where a phrase similar to “at least one of A, B, and C” is used in the claims, it is intended that the phrase be interpreted to mean that A alone may be present in an embodiment, B alone may be present in an embodiment, C alone may be present in an embodiment, or that any combination of the elements A, B and C may be present in a single embodiment; for example, A and B, A and C, B and C, or A, B, and C. In some cases, “at least one of item A, item B, and item C” may mean, for example, without limitation, two of item A, one of item B, and ten of item C; four of item B and seven of item C; or some other suitable combination.

All ranges and ratio limits disclosed herein may be combined. Unless otherwise indicated, the terms “first,” “second,” etc. are used herein merely as labels, and are not intended to impose ordinal, positional, or hierarchical requirements on the items to which these terms refer. Moreover, reference to, e.g., a “second” item does not require or preclude the existence of, e.g., a “first” or lower-numbered item, and/or, e.g., a “third” or higher-numbered item.

Any reference to attached, fixed, connected or the like may include permanent, removable, temporary, partial, full and/or any other possible attachment option. Additionally, any reference to without contact (or similar phrases) may also include reduced contact or minimal contact. In the above description, certain terms may be used such as “up,” “down,” “upper,” “lower,” “horizontal,” “vertical,” “left,” “right,” and the like. These terms are used, where applicable, to provide some clarity of description when dealing with relative relationships. But, these terms are not intended to imply absolute relationships, positions, and/or orientations. For example, with respect to an object, an “upper” surface can become a “lower” surface simply by turning the object over. Nevertheless, it is still the same object.

Additionally, instances in this specification where one element is “coupled” to another element can include direct and indirect coupling. Direct coupling can be defined as one element coupled to and in some contact with another element. Indirect coupling can be defined as coupling between two elements not in direct contact with each other, but having one or more additional elements between the coupled elements. Further, as used herein, securing one element to another element can include direct securing and indirect securing. Additionally, as used herein, “adjacent” does not necessarily denote contact. For example, one element can be adjacent another element without being in contact with that element.

Although exemplary embodiments of the present disclosure are set forth herein, it should be appreciated that the disclosure is not so limited. For example, although reactor systems are described in connection with various specific configurations, the disclosure is not necessarily limited to these examples. Various modifications, variations, and enhancements of the system and method set forth herein may be made without departing from the spirit and scope of the present disclosure.

The subject matter of the present disclosure includes all novel and nonobvious combinations and subcombinations of the various systems, components, and configurations, and other features, functions, acts, and/or properties disclosed herein, as well as any and all equivalents thereof.

1. A substrate lift assembly comprising:
a susceptor comprising a susceptor top surface, a susceptor bottom surface, and a susceptor body spanning therebetween;
a plurality of lift pins, each lift pin of the plurality of lift pins extending through the body;
a plate comprising a plate top surface proximate the susceptor bottom surface and a plate bottom surface opposite the plate top surface;
a sensor; and
a lift mechanism to move the susceptor relative to the plate,
wherein the sensor determines one or more of presence information and condition information associated with each of the lift pins of the plurality of lift pins.

2. The substrate lift assembly of claim 1, comprising a plurality of lift pin pads corresponding to each lift pin of the plurality of lift pins.

3. The substrate lift assembly of claim 2, wherein the substrate lift assembly comprises a plurality of sensors, including the sensor, and wherein each of the plurality of sensors is formed on or within a lift pin pad of the plurality of lift pin pads.

4. The substrate lift assembly of claim 1, wherein the sensor comprises one or more of a magnetic proximity sensor, an optical sensor, a diffuse sensor, a resistance temperature detector, a linear variable differential transducer, a load cell, a piezoelectric device, a voltmeter, or a strain gauge.

5. The substrate lift assembly of claim 1, wherein each lift pin comprises a head, a base, and a lift pin body spanning therebetween, wherein a cross section of the head and a cross section of the base are greater than a cross section of the lift pin body.

6. The substrate lift assembly of claim 1, wherein the sensor is coupled to the plate bottom surface.

7. The substrate lift assembly of claim 1, further comprising a feedthrough coupled to the plate, wherein at least a portion of the sensor is within an opening of the plate.

8. The substrate lift assembly of claim 1, further comprising a controller coupled to the sensor.

9. The substrate lift assembly of claim 8, further comprising an amplifier coupled between the sensor and the controller.

10. The substrate lift assembly of claim 1, wherein the plate comprises a raised section and wherein the sensor is coupled to the plate in the raised section.

11. The substrate lift assembly of claim 1, wherein the sensor comprises a light emitter and a light detector.

12. The substrate lift assembly of claim 1, wherein the sensor comprises a load cell.

13. The substrate lift assembly of claim 1, wherein the lift pin comprises Sialon, Si₃N₄, or SiC.

14. The substrate lift assembly of claim 1, further comprising a prism.

15. The substrate lift assembly of claim 1, further comprising a prism coupled to the plate.

16. A method of determining one or more of a presence and a condition of one or more lift pins, the method comprising:
providing the one or more lift pins within a susceptor;
providing a sensor proximate the one or more lift pins;
moving the susceptor; and
sensing one or more of:
a force exerted by the one or more lift pins;
a light transmission;
a resistance;
linear movement of the one or more lift pins;
a lift pin pad contact and/or release time associated with each of the one or more lift pins;
a voltage; and
a strain.

17. The method according to claim 16, wherein the step of sensing comprises emitting light and detecting the presence or absence of the light.

18. The method according to claim 16, wherein the step of sensing comprises emitting light and measuring an amount of the light.

19. The method according to claim 16, wherein the step of sensing comprises measuring a magnetic force.

20. A system comprising:
a reaction chamber;
a lift assembly comprising:
a susceptor comprising a susceptor top surface, a susceptor bottom surface, and a susceptor body spanning therebetween;
a plurality of lift pins, each lift pin of the plurality of lift pins through the susceptor body;
a plate comprising a plate top surface proximate the susceptor bottom surface and a plate bottom surface opposite the plate top surface;
a sensor; and
a lift mechanism to move the susceptor relative to the plate,
wherein the sensor determines one or more of presence information and condition information associated with each of the lift pins of the plurality of lift pins; and
a controller configured to move the susceptor and to cease operation of the system based on one or more of the presence information and the condition information.
